(19) United States
(12) Patent Application Publication
(10) Pub. No.: US 2024/0321710 A1
(43) Pub. Date: Sep. 26, 2024

(54) SEMICONDUCTOR PACKAGE HAVING COMPENSATED ELECTRICAL CHANNEL PATHS

(71) Applicant: SK hynix Inc., Icheon-si Gyeonggi-do (KR)

(72) Inventor: Ki Yong LEE, Icheon-si Gyeonggi-do (KR)

(73) Assignee: SK hynix Inc., Icheon-si Gyeonggi-do (KR)

(21) Appl. No.: 18/510,481

(22) Filed: Nov. 15, 2023

(30) Foreign Application Priority Data
Mar. 21, 2023 (KR) 10-2023-0036451

(51) Int. Cl. H01L 23/498; H01L 23/00; H01L 25/065; H10B 80/00

(52) U.S. Cl. CPC H01L 23/49838; H01L 23/49822; H01L 24/48; H01L 24/49; H01L 25/0652; H10B 80/00; H01L 24/16; H01L 2224/16225; H01L 2224/48145; H01L 2224/48227; H01L 2224/4903; H01L 2924/1431

(57) ABSTRACT

A semiconductor package includes a control chip and a memory stack mounted on a substrate, and first and second stack bonding wires. The memory stack includes first and second memory stacks. The substrate includes first and second bond fingers. The first and second bonding wires connect the first and second bond fingers to the first and second memory stack, respectively. A first electrical path connecting a first channel pad of the control chip to the first bond finger is longer than a second electrical path connecting a second channel pad of the control chip to the second bond finger. The first stack bonding wire is shorter than the second stack bonding wire.

### CROSS-REFERENCE TO RELATED APPLICATION

The present application claims priority under 35 U.S.C 119(a) to Korean Patent Application No. 10-2023-0036451, filed on Mar. 21, 2023, in the Korean Intellectual Property Office, which is incorporated herein by reference in its entirety.

### BACKGROUND

### 1. Field

Embodiments of the present disclosure are directed to a semiconductor package including a control chip and stacked memory stacks and having compensated electrical channel paths.

### 2. Description of the Related Art

As the operation of semiconductor devices becomes faster, temporal differences of signals caused by the differences in the physical lengths of channel paths are emerging as a problem to be solved.

### SUMMARY

A semiconductor package in accordance with an embodiment of the present disclosure includes a control chip and a memory stack mounted on a substrate, wherein the control chip includes a first channel pad and a second channel pad and the memory stack includes a first memory stack and a second memory stack stacked over the first memory stack. The substrate includes first and second electrical paths. The first electrical path includes a first bonding pad electrically connected to the first channel pad, a first substrate interconnection electrically connected to the first bonding pad, and a first bond finger electrically connected to the first substrate interconnection. The second electrical path includes a second bonding pad electrically connected to the second channel pad, a second substrate interconnection electrically connected to the second bonding pad, and a second bond finger electrically connected to the second substrate interconnection. The first stack bonding wire electrically connects the first bond finger to the first memory stack. The second stack bonding wire electrically connects the second bond finger to the second memory stack. The first stack bonding wire is shorter than the second stack bonding wire. Additionally, the first electrical path is longer than the second electrical path.

A semiconductor package in accordance with another embodiment of the present disclosure includes: a substrate having an upper surface and a lower surface; a control chip and a memory stack mounted on the upper surface of the substrate, wherein the memory stack includes a first memory stack and a second memory stack stacked over the first memory stack in a direction toward the control chip; a first channel connector electrically connecting a first bonding pad of the substrate to a first channel pad of the control chip; a second channel connector electrically connecting a second bonding pad of the substrate to a second channel pad of the control chip; a first stack bonding wire disposed on a first side of the memory stack and electrically connecting a first bond finger of the substrate to the first memory stack; and a second stack bonding wire disposed on the first side of the memory stack and electrically connecting a second bond finger of the substrate to the second memory stack. The substrate includes: a first middle substrate interconnection; a second middle substrate interconnection; a first substrate via that vertically passes through the first middle substrate interconnection and electrically connects the first bonding pad and the second middle substrate interconnection to each other; and a second substrate via that vertically passes through the first middle substrate interconnection and electrically connects the first bond finger to the second middle substrate interconnection. The first stack bonding wire is shorter than the second stack bonding wire. Also, a first electrical path from the first bonding pad to the first bond finger is longer than a second electrical distance from the second bonding pad to the second bond finger.

### BRIEF DESCRIPTION OF THE DRAWINGS

FIG. 1 is a side cross-sectional view schematically illustrating a semiconductor package in accordance with an embodiment of the present disclosure.

FIG. 2 is an enlarged view illustrating conductive constituent elements of a substrate.

FIG. 3 is an enlarged view illustrating a control chip bonded to the substrate.

FIG. 4 is an enlarged view illustrating a memory stack.

FIG. 5 is an enlarged view illustrating the control chip bonded to the substrate.

FIG. 6 is a side cross-sectional view schematically illustrating a semiconductor package in accordance with an embodiment of the present disclosure.

FIG. 7 is an enlarged view illustrating the conductive constituent elements of the substrate.

FIG. 8 is an enlarged view illustrating the control chip bonded to the substrate.

FIG. 9 is an enlarged view illustrating a memory stack.

FIGS. 10A and 10B are top views illustrating wire bonding methods in accordance with embodiments of the present disclosure.

### DETAILED DESCRIPTION

Embodiments of the present disclosure are described below in more detail with reference to the accompanying drawings. The present disclosure may, however, be embodied in different forms and should not be construed as limited to the embodiments set forth herein. Rather, these embodiments are provided so that this disclosure will be enabling to those skilled in the art. Throughout the disclosure, like reference numerals refer to like parts throughout the various figures and embodiments of the present disclosure.

The drawings are not necessarily to scale, and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Some embodiments of the present disclosure are directed to a semiconductor package with compensated electrical channel paths. For example, some embodiments of the present disclosure are directed to a structure that may compensate for the temporal differences of signals caused by the differences in the physical lengths of bonding wires that electrically connect memory stacks.

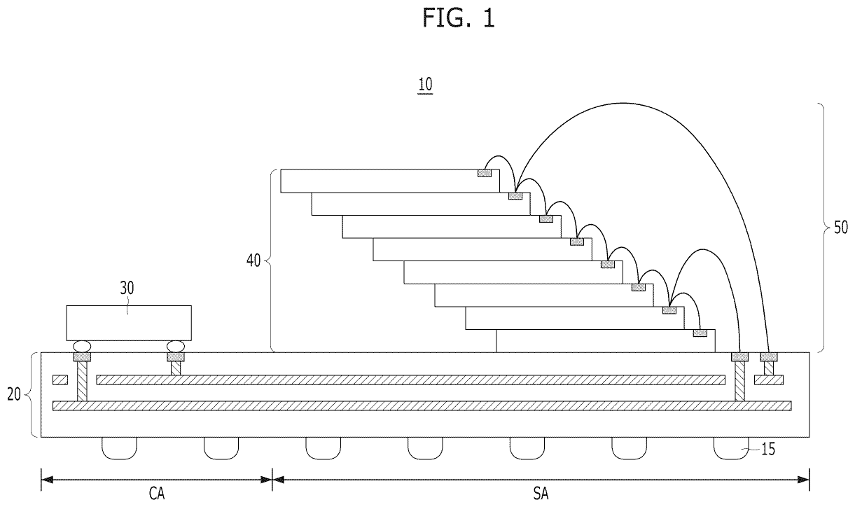

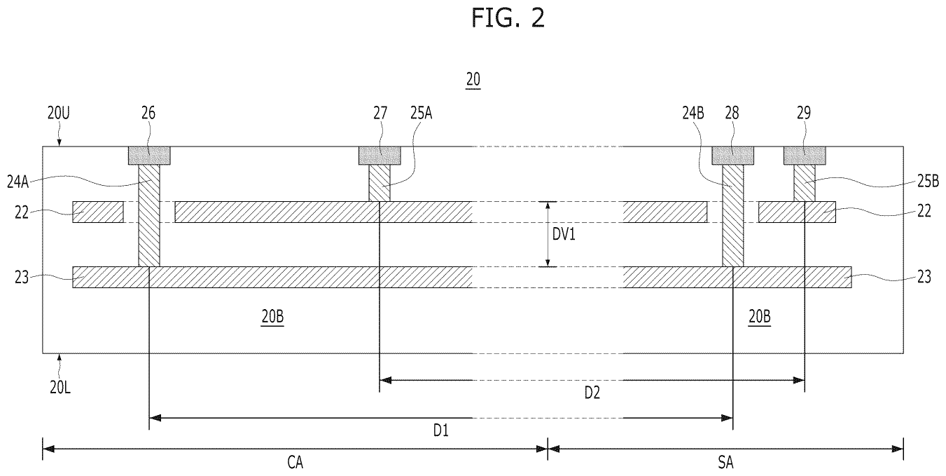

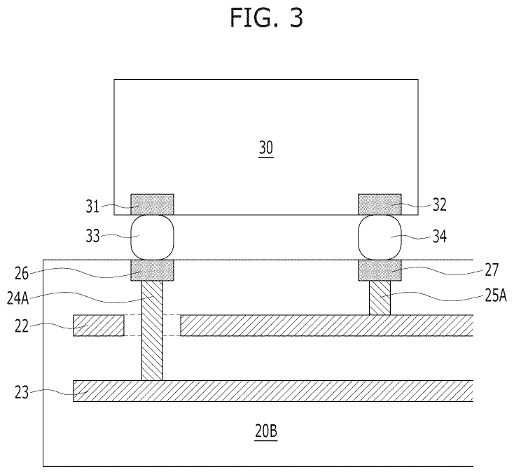

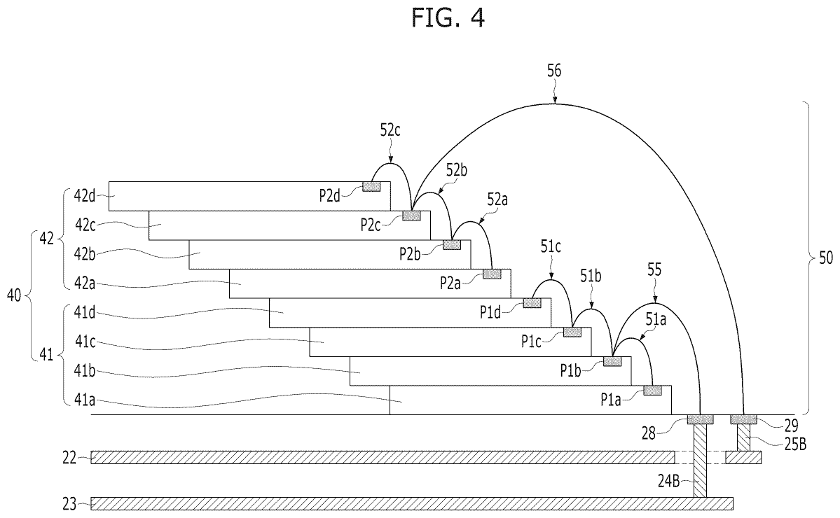

FIG. 1 is a side cross-sectional view schematically illustrating a semiconductor package 10 in accordance with an embodiment of the present disclosure, and FIGS. 2 to 4 are partially enlarged views of FIG. 1.

Referring to FIGS. 1 to 4, the semiconductor package 10 may include a control chip 30 and a memory stack 40 mounted on a substrate 20. The semiconductor package 10 may further include a first channel connector 33 and a second channel connector 34. The semiconductor package 10 may further include a bonding wire structure 50. The semiconductor package 10 may further include external bumps 15 for electrical connection to external systems, e.g., a host or a main board.

The substrate 20 may include substrate interconnections 22 and 23, substrate vias 24A, 24B, 25A, and 25B, bonding pads 26 and 27, and bond fingers 28 and 29 formed in a substrate body 20B. For example, the substrate 20 may include a printed circuit board (PCB). According to another embodiment of the disclosure, the substrate 20 may include a silicon redistribution layer.

The substrate body 20B may have a lower surface 20L and an upper surface 20U opposite to the lower surface 20L. A pad structure (not shown) to contact and to be bonded to the external bumps 15 may be formed on the lower surface 20L of the substrate body 20B. The substrate 20 may include a chip mounting area CA and a stack mounting area SA. The control chip 30 may be mounted on the upper surface 20U of the chip mounting area CA of the substrate 20, and the memory stack 40 may be mounted on the upper surface of the stack mounting area SA of the substrate 20. The substrate body 20B may include a dielectric material, e.g., a prepreg layer.

The substrate interconnections 22 and 23 may include a conductive upper substrate interconnection 22 and a conductive lower substrate interconnection 23. The lower substrate interconnection 23 may be disposed close to the lower surface 20L of the substrate body 20B, and the upper substrate interconnection 22 may be disposed close to the upper surface 20U of the substrate body 20B. The upper substrate interconnection 22 and the lower substrate interconnection 23 may be signal interconnection that transfers signals. For example, the upper substrate interconnection 22 and the lower substrate interconnection 23 may transfer clock signals, address signals, strobe signals, and data signals. According to another embodiment of the disclosure, the substrate 20 may further include a power substrate interconnection (a power plane) that is disposed between the upper substrate interconnection 22 and the lower substrate interconnection 23 to transfer power, and a ground substrate interconnection (a ground plane) for grounding. To better understand the inventive concept of the present disclosure, the power substrate interconnection and the ground substrate interconnection may be omitted.

The substrate vias 24A, 24B, 25A, and 25B may include long substrate vias 24A and 24B and short substrate vias 25A and 25B. The long substrate vias 24A and 24B may include a first long substrate via 24A and a second long substrate via 24B. The short substrate vias 25A and 25B may include a first short substrate via 25A and a second short substrate via 25B. The long substrate vias 24A and 24B may penetrate the upper substrate interconnection 22 in a vertical direction. For example, the long substrate vias 24A and 24B and the upper substrate interconnections 22 may be physically spaced apart from each other and electrically isolated. The long substrate vias 24A and 24B may have a vertical electrical height that is longer than the short substrate vias 25A and 25B by a first vertical distance DV1. The first vertical distance DV1 may correspond to the distance between the upper surface of the upper substrate interconnection 22 and the upper surface of the lower substrate interconnection 23. The first long substrate via 24A and the first short substrate via 25A may be disposed in the chip mounting area CA to be electrically connected to the control chip 30. The second long substrate via 24B and the second short substrate via 25B may be disposed in the stack mounting area SA to be electrically connected to the memory stack 40.

The bonding pads 26 and 27 may be disposed in the chip mounting area CA, and the bond fingers 28 and 29 may be disposed in the stack mounting area SA. The bonding pads 26 and 27 may include a first bonding pad 26 and a second bonding pad 27. The bond fingers 28 and 29 may include a first bond finger 28 and a second bond finger 29. The first bonding pad 26 may be disposed farther from the stack mounting area SA than the second bonding pad 27. Therefore, the second bonding pad 27 may be disposed closer to the bond fingers 28 and 29 of the stack mounting area SA than the first bonding pad 26. The first bond finger 28 may be disposed closer to the chip mounting area CA than the second bond finger 29. Therefore, the second bond finger 29 may be disposed farther from the control chip 30 and the bonding pads 26 and 27 than the first bond finger 28. The electrical path between the first bonding pad 26 and the first bond finger 28 may be longer than the electrical path between the second bonding pad 27 and the second bond finger 29.

The first long substrate via 24A may electrically and physically connect the first bonding pad 26 to the lower substrate interconnection 23. The second long substrate via 24B may electrically and physically connect the first bond finger 28 and the lower substrate interconnection 23. The first short substrate via 25A may electrically and physically connect the second bonding pad 27 to the upper substrate interconnection 22. The second short substrate via 25B may electrically and physically connect the second bond finger 29 to the upper substrate interconnection 22. The first long substrate via 24A and the second long substrate via 24B may be physically spaced apart in a horizontal direction and electrically connected to each other with a first horizontal distance D1. For example, the lower substrate interconnection 23 may have a first electrical signal path corresponding to the first horizontal distance D1 from the portion connected to the first long substrate via 24A to the portion connected to the second long substrate via 24B. The first short substrate via 25A and the second short substrate via 25B may be physically spaced apart in the horizontal direction and electrically connected to each other with a second horizontal distance D2. For example, the upper substrate interconnection 22 may have a second electrical signal path corresponding to the second horizontal distance D2 from the portion connected to the first short substrate via 25A to the portion connected to the second short substrate via 25B. The first horizontal distance D1 may be greater than the second horizontal distance D2. In other words, the first electrical signal path of the lower substrate interconnection 23 may be greater than the second electrical signal path of the upper substrate interconnection 22.

The control chip 30 may be disposed between an external processor, e.g., a host, and the memory stack 40, and may include a buffer circuit. For example, the control chip 30 may include a control logic chip, e.g., a chipset. The control chip 30 may have a first channel pad 31 and a second channel pad 32. The first channel pad 31 may be disposed farther from the memory stack 40 than the second channel pad 32. The first channel pad 31 may be electrically connected to the first bonding pad 26 through the first channel connector 33. The second channel pad 32 may be electrically connected to the second bonding pad 27 through the second channel connector 34. The first channel connector 33 and the second channel connector 34 may include a solder material. For example, the control chip 30 may be bonded to the substrate 20 by a flip chip bonding method. The control chip 30 may be provided in the form of a packaged semiconductor chip or a chiplet of a wafer state.

The memory stack 40 may include a first memory stack 41 and a second memory stack 42. For example, the second memory stack 42 may be offset-stacked in a staircase over the first memory stack 41 in a direction toward the control chip 30.

The first memory stack 41 may include a first lower memory chip 41a, first middle memory chips 41b and 41c, and a first upper memory chip 41d. The first middle memory chips 41b and 41c may include a first middle lower memory chip 41b and a first middle upper memory chip 41c. The first lower memory chip 41a, the first middle lower memory chip 41b, the first middle upper memory chip 41c, and the first upper memory chip 41d may include first chip pads P1a to P1d, respectively. For example, the first lower memory chip 41a may include a first lower chip pad P1a disposed to be adjacent to an edge on an upper surface, and the first middle lower memory chip 41b may include a first middle lower chip pad P1b disposed to be adjacent to an edge on an upper surface. The first middle upper memory chip 41c may include a first middle upper chip pad Plc disposed to be adjacent to an edge on an upper surface, and the first upper memory chip 41d may include a first upper chip pad P1d disposed to be adjacent to an edge on an upper surface. The first lower memory chip 41a, the first middle lower memory chip 41b, the first middle upper memory chip 41c, and the first upper memory chip 41d may be offset-stacked in a staircase. Accordingly, the first lower chip pad P1a of the first lower memory chip 41a, the first middle lower chip pad P1b of the first middle lower memory chip 41b, the first middle upper chip pad Plc of the first middle upper memory chip 41c, and the first upper chip pad P1d of the first upper memory chip 41d may be exposed in a staircase.

The second memory stack 42 may include a second lower memory chip 42a, second middle memory chips 42b and 42c, and a second upper memory chip 42d. The second middle memory chips 42b and 42c may include a second middle lower memory chip 42b and a second middle upper memory chip 42c. The second lower memory chip 42a, the second middle lower memory chip 42b, the second middle upper memory chip 42c, and the second upper memory chip 42d may include second chip pads P2a to P2d, respectively. For example, the second lower memory chip 42a may include a second lower chip pad P2a disposed to be adjacent to an edge on an upper surface, and the second middle lower memory chip 42b may include a second middle lower chip pad P2b disposed to be adjacent to an edge on an upper surface. The second middle upper memory chip 42c may include a second middle upper chip pad P2c disposed to be adjacent to an edge on an upper surface. The second upper memory chip 42d may include a second upper chip pad P2d disposed to be adjacent to an edge on an upper surface. The second lower memory chip 42a, the second middle lower memory chip 42b, the second middle upper memory chip 42c, and the second upper memory chip 42d may be offset-stacked in a staircase. Accordingly, the second lower chip pad P2a of the second lower memory chip 42a, the second middle lower chip pad P2b of the second middle lower memory chip 42b, the second middle upper chip pad P2c of the second middle upper memory chip 42c, and the second upper chip pad P2d of the second upper memory chip 42d may be exposed in a staircase. The memory chips 41a to 41d and 42a to 42d may also be provided in a chiplet form.

The bonding wire structure 50 may include first and second chip bonding wires 51a to 51c and 52a to 52c, and first and second stack bonding wires 55 and 56. The first chip bonding wires 51a to 51d may electrically and physically connect the first chip pads P1a to P1d of the first memory chips 41a to 41d of the first memory stack 41 to each other. For example, the first chip bonding wires 51a to 51c may include a first lower chip bonding wire 51a connecting the first lower chip pad P1a to the first middle lower chip pad P1b, a first middle chip bonding wire 51b connecting the first middle lower chip pad P1b to the first middle upper chip pad P1c, and a first upper chip bonding wire 51c connecting the first middle upper chip pad Plc to the first upper chip pad P1d. The second chip bonding wires 52 may electrically and physically connect the second chip pads P2a to P2d of the second memory chips 42a to 42d of the second memory stack 42 to each other. For example, the second chip bonding wires 52a to 52c may include a second lower chip bonding wire 52a connecting the second lower chip pad P2a to the second middle lower chip pad P2b, a second middle chip bonding wire 52b connecting the second middle lower chip pad P2b to the second middle upper chip pad P2c, and a second upper chip bonding wire 52c connecting the second middle upper chip pad P2c to the second upper chip pad P2d. In other words, the first and second chip bonding wires 51 and 52 may connect the chip pads Pia to P1d or P2a to P2d of the two neighboring memory chips 41a to 41d or 42a to 42d to each other, respectively. The first upper chip pad P1d of the first upper memory chip 41d of the first memory stack 41 and the second lower chip pad P2a of the second lower memory chip 42a of the second memory stack 42 may not be directly connected to each other.

The first stack bonding wire 55 may electrically and physically connect one of the first middle chip pads P1b and Plc of the first middle memory chips 41b and 41c of the first memory stack 41 to the first bond finger 28. The second stack bonding wire 56 may electrically and physically connect to one of the second middle chip pads P2b and P2c of the second middle memory chips 42b and 42c of the second memory stack 42 to the second bond finger 29. The stack bonding wires 55 and 56 may be connected to one of the middle memory chips 41b, 41c, 42b, and 42c to reduce deviations of the electrical distances between the bond fingers 28 and 29 and the memory chips 41a to 41d and 42a to 42d. In the drawing, the first stack bonding wire 55 is illustrated to connect the first middle upper chip pad Plc of the first middle upper memory chip 41c to the first bond finger 28. According to another embodiment of the disclosure, the first stack bonding wire 55 may connect the first middle lower chip pad P1b of the first middle lower memory chip 41b to the first bond finger 28. In the drawing, the second stack bonding wire 56 is illustrated to connect the second middle upper chip pad P2b of the second middle lower memory chip 42b to the second bond finger 29. According to another embodiment of the disclosure, the second stack bonding wire 56 may connect the second middle upper chip pad P2c of the second middle upper memory chip 42c to the second bond finger 29. Because the first stack bonding wire 55 is connected to the first memory stack 41 stacked in the lower portion, it may be shorter than the second stack bonding wire 56 that is connected to the second memory stack 42 stacked in the upper portion. Accordingly, a signal difference may occur due to the difference between the length of the first stack bonding wire 55 and the length of the second stack bonding wire 56. According to the embodiment of the disclosure, the bonding wire structure 50 may be disposed to be adjacent to one side of the memory stack 40.

The first channel pad 31 of the control chip 30, the first channel connector 33, the first bonding pad 26, the first long substrate via 24A, the lower substrate interconnection 23, the second long substrate via 24B, the first bond finger 28, the first stack bonding wires 55, and the first chip bonding wires 51 may form a first channel path. The second channel pad 32 of the control chip 30, the second channel connector 34, the second bonding pad 27, the first short substrate via 25A, the upper substrate interconnection 22, the second short substrate via 25B, the second bond finger 29, the second stack bonding wire 56, and the second chip bonding wires 52 may form a second channel path. The second stack bonding wire 56 of the second channel may be longer than the first stack bonding wire 55 of the first channel path. The first long substrate via 24A and the second long substrate via 24B of the first channel path may have an electrical vertical height that is longer than the first short substrate via 25A and the second short substrate via 25B of the second channel path by the first vertical distance DV1, respectively. Accordingly, the first vertical distance DV1, i.e., height distance of the first and second long substrate vias 24A and 24B and the first and second short substrate vias 25A and 25B may be able to compensate for the difference in the electrical paths caused by the difference in the lengths of the first and second stack bonding wires 55 and 56. The difference between the first horizontal distance D1 between the first long substrate via 24A and the second long substrate via 24B, that is, the first electrical signal path of the lower substrate interconnection 23, and the second horizontal distance D2 between the first short substrate via 25A and the second short substrate via 25B, that is, the second electrical signal path of the upper substrate interconnection 23, can compensate for the difference between the length of the first stack bonding wire 55 and the length of the second stack bonding wire 56. Therefore, the difference in the signal paths caused by the difference in lengths of the bonding wires 55 and 56 that occurs according to the stacked position (i.e., height or level) of the memory chips 41a to 41d and 42a to 42d of the memory stacks 40, 41, and 42 may be compensated for by the positions of the bonding pads 26 and 27, the positions of the bond fingers 28 and 29, the vertical lengths of the substrate vias 24A, 24B, 25A, and 25B, and the effective signal paths of the substrate interconnections 22 and 23.

The external bumps 15 may include a solder material or a metal. According to another embodiment of the disclosure, the semiconductor package 10 may further include an encapsulation material that covers the control chip 30 and the memory stack 40 over the substrate 20. The encapsulation material may include a resin, e.g., epoxy molding compound (EMC).

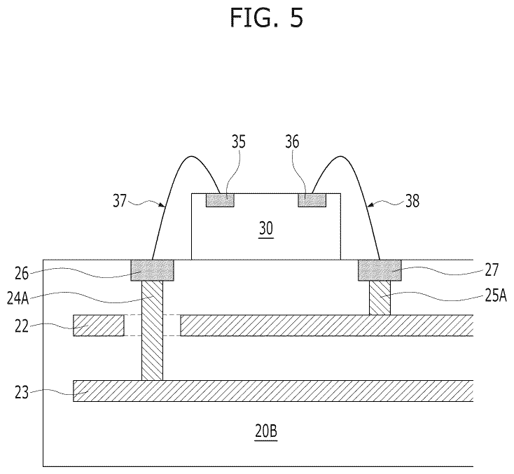

FIG. 5 illustrates the control chip 30 bonded to the substrate 20 in accordance with another embodiment of the present disclosure. Referring to FIG. 5, the control chip 30 may be bonded to the substrate 20 by using a wire bonding method. The control chip 30 may include a first channel pad 35 and a second channel pad 36 that are disposed on the upper surface. The first channel pad 35 may be electrically connected to the first bonding pad 26 through the first channel wire 37. The second channel pad 36 may be electrically connected to the second bonding pad 27 through the second channel wire 38.

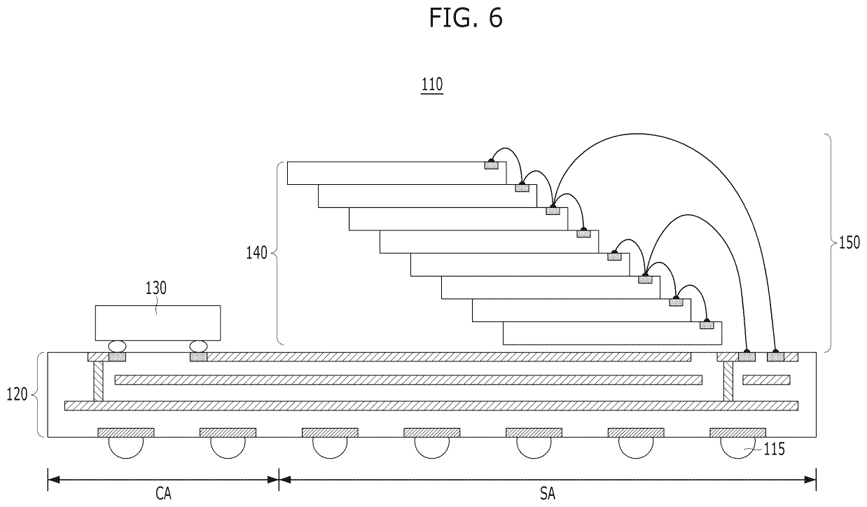

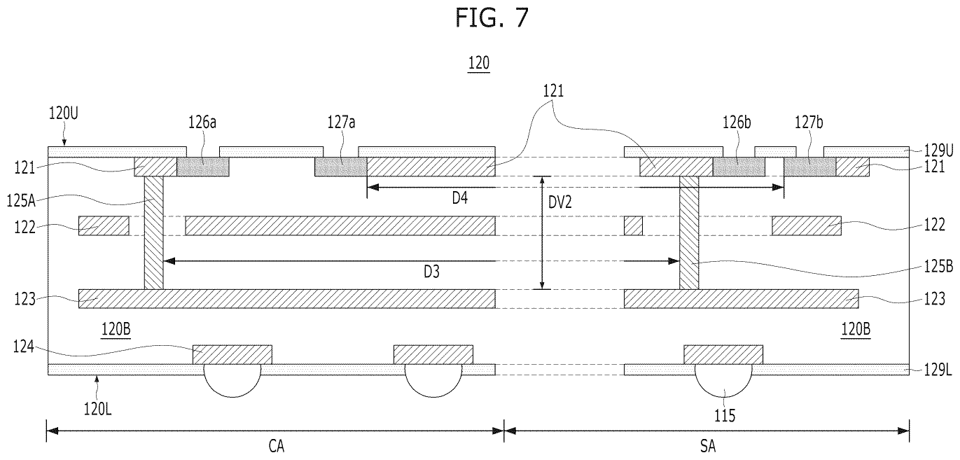

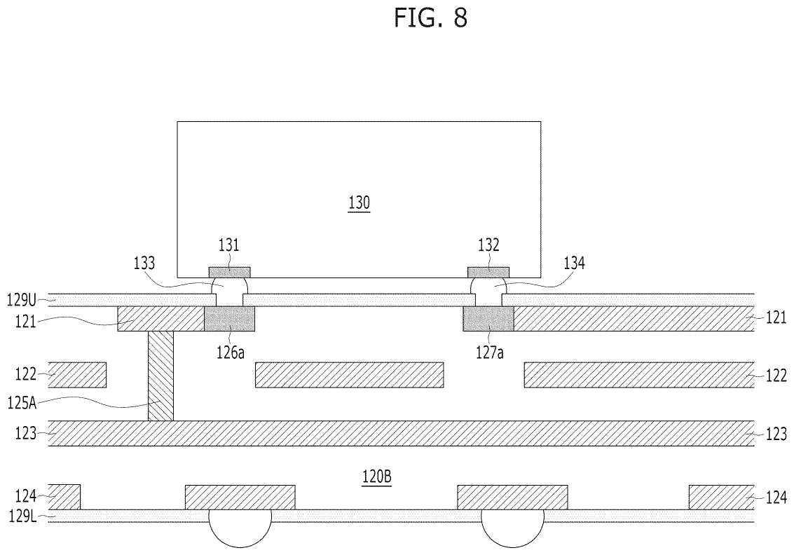

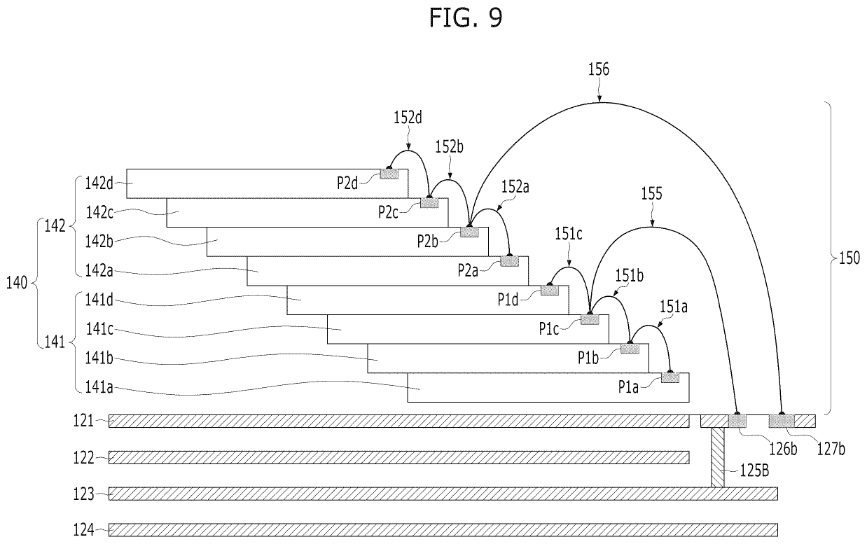

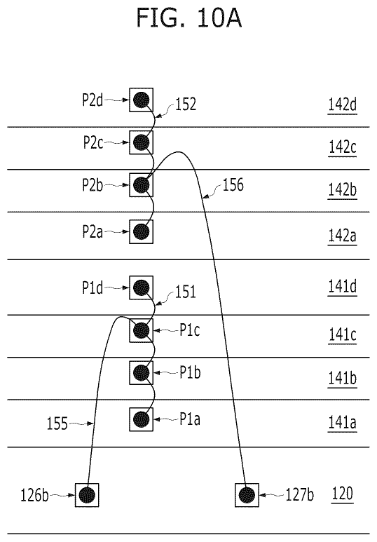

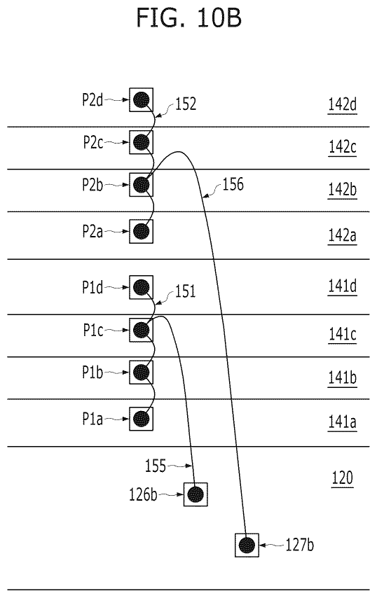

FIG. 6 is a side cross-sectional view schematically illustrating a semiconductor package 110 in accordance with an embodiment of the present disclosure. FIGS. 7 to 9 are an enlarged views illustrating a portion of FIG. 6, and FIGS. 10A and 10B are partial top views.

Referring to FIGS. 6 to 9, the semiconductor package 110 may include a control chip 130 and a memory stack 140 that are mounted on a substrate 120. The semiconductor package 110 may further include a first channel connector 133 and a second channel connector 134. The semiconductor package 110 may further include a bonding wire structure 150. The semiconductor package 110 may further include external bumps 115.

The substrate 120 may include substrate interconnections 121 to 124, substrate vias 125A and 125B, bonding pads 126a and 127a, and bond fingers 126b and 127b that are formed in a substrate body 120B. For example, the substrate 120 may include a printed circuit board (PCB). According to another embodiment of the disclosure, the substrate 120 may include a silicon redistribution layer.

The substrate interconnections 121 to 124 may include an upper substrate interconnection 121, a middle upper substrate interconnection 122, a middle lower substrate interconnection 123, and a lower substrate interconnection 124. The upper substrate interconnection 121 and the middle lower substrate interconnection 123 may transfer electrical signals. The upper substrate interconnection 121 may provide bonding pads 126a and 127a to be electrically connected to the control chip 130 and bond fingers 126b and 127b to be electrically connected to the memory stack 140. For example, the bonding pads 126a and 127a and the bond fingers 126b and 127b may be portions of the upper substrate interconnection 121.

The middle upper substrate interconnection 122 may transfer a power voltage or a ground voltage. The lower substrate interconnection 124 may transfer electrical signals, the power voltage, and the ground voltage. The lower substrate interconnection 124 may provide pad structures to be connected to the external bumps 115.

The substrate body 120B may have a lower surface 120L and an upper surface 120U opposite to the lower surface 120L. The control chip 130 and the memory stack 140 may be mounted on the upper surface 120U of the substrate body 120B. The external bumps 115 may be disposed on the lower surface 120L of the substrate body 120B. The substrate 120 may further include a lower solder resist 129L disposed on the lower surface 120L of the substrate body 120B and an upper solder resist 129U disposed on the upper surface 120U of the substrate body 120B. The upper solder resist 129U may expose portions of the upper substrate interconnection 121 to provide bonding pads 126a and 127a and bond fingers 126b and 127b. The lower solder resist 129L may expose portions of the lower substrate interconnection 124 to provide pad structures on which the external bumps 115 are to be disposed. The substrate 120 may include a chip mounting area CA and a stack mounting area SA. The control chip 130 may be mounted on the upper surface 120U of the chip mounting area CA of the substrate 120, and the memory stack 140 may be mounted on the upper surface 120U of the stack mounting area SA of the substrate 120. The substrate body 120B may include a dielectric material, e.g., a prepreg layer.

The substrate vias 125A and 125B may pass through the middle upper substrate interconnection 122 to physically and electrically connect the upper substrate interconnection 121 to the middle lower substrate interconnection 123. The substrate vias 125A and 125B may include a first substrate via 125A and a second substrate via 125B. The first substrate via 125A may be disposed in the chip mounting area CA to connect a portion of the upper substrate interconnection 121, which is electrically connected to the control chip 130, to the middle lower substrate interconnection 123. For example, the first substrate via 125A may vertically pass through the middle upper substrate interconnection 122 to electrically connect the first bonding pad 126a and the middle lower substrate interconnection 123.

The second substrate via 125B may be disposed in the stack mounting area SA to connect a portion of the upper substrate interconnection 121, which is electrically connected to the memory stack 140, to the middle lower substrate interconnection 123. For example, the second substrate via 125B may vertically penetrate the middle upper substrate interconnection 122 to electrically connect the first bond finger pad 126b to the middle lower substrate interconnection 123. The first substrate via 125A and the second substrate via 125B may be electrically connected to each other through the middle lower substrate interconnection 123.

The bonding pads 126a and 127a may be disposed in the chip mounting area CA, and the bond fingers 126b and 127b may be disposed in the stack mounting area SA. The bonding pads 126a and 127a may include a first bonding pad 126a and a second bonding pad 127a. The bond fingers 126b and 127b may include a first bond finger 126b and a second bond finger 127b. The first bonding pad 126a may be disposed farther from the stack mounting area SA than the second bonding pad 127a. Therefore, the second bonding pad 127a may be disposed closer to the bond fingers 126b and 127b of the stack mounting area SA than the first bonding pad 126a. The first bond finger 126b may be disposed closer to the chip mounting area CA than the second bond finger 127b. Therefore, the second bond finger 127b may be disposed farther from the control chip 130 and the bonding pads 126a and 127a than the first bond finger 126b. The electrical path between the first bonding pad 126a and the first bond finger 126b may be longer than the electrical path between the second bonding pad 127a and the second bond finger 127b. For example, the first substrate via 125A and the second substrate via 125B may be electrically connected to be physically spaced apart in the horizontal direction to correspond to a third horizontal distance D3. The second bonding pad 127a and the second bond finger 127b may be electrically connected to be physically spaced apart in the horizontal direction to correspond to a fourth horizontal distance D4. The third horizontal distance D3 may be greater than the fourth horizontal distance D4. Accordingly, the electrical path from the first bonding pad 126a to the first bond finger 126b through the upper substrate interconnection 121 in the chip mounting area CA, the first substrate via 125A, the lower middle substrate interconnection 123, the second substrate via 125B, and the upper substrate interconnection 121 in the stack mounting area SA may be longer than the electrical path from the second bonding pad 127a to the second bond finger 127b through the upper substrate interconnection 121.

The control chip 130 may be electrically disposed between an external processor, e.g., a host, and the memory stack 140, and may include a buffer circuit. According to another embodiment of the disclosure, the control chip 130 may include a control logic chip, e.g., a chipset. The control chip 130 may include a first channel pad 131 and a second channel pad 132. The first channel pad 131 may be disposed farther from the memory stack 140 than the second channel pad 132. The first channel pad 131 may be electrically connected to the first bonding pad 126a through the first channel connector 133. The second channel pad 132 may be electrically connected to the second bonding pad 127a through the second channel connector 134. The first channel connector 133 and the second channel connector 134 may include a solder material. For example, the control chip 130 may be bonded to the substrate 120 by a flip chip bonding method. The control chip 130 may be provided in the form of a packaged semiconductor chip or a chiplet of a wafer state.

The memory stack 140 may include a first memory stack 141 and a second memory stack 142. For example, the second memory stack 142 may be offset-stacked in a staircase over the first memory stack 141 in a direction toward the control chip 30.

The first memory stack 141 may include a first lower memory chip 141a, first middle memory chips 141b and 141c, and a first upper memory chip 141d. The first middle memory chips 141b and 141c may include a first middle lower memory chip 141b and a first middle upper memory chip 141c. The first lower memory chip 141a, the first middle lower memory chip 141b, the first middle upper memory chip 141c, and the first upper memory chip 141d may include first chip pads P1a to P1d, respectively. For example, the first lower memory chip 141a may include the first lower chip pad P1a which is disposed adjacent to an edge on an upper surface, and the first middle lower memory chip 141b may include the first middle lower chip pad P1b which is disposed adjacent to an edge on an upper surface. The first middle upper memory chip 141c may include the first middle upper chip pad Plc which is disposed adjacent to an edge on an upper surface, and the first upper memory chip 141d may include the first upper chip pad P1d which is disposed adjacent to an edge on an upper surface. The first lower memory chip 141a, the first middle lower memory chip 141b, the first middle upper memory chip 141c, and the first upper memory chip 141d may be offset-stacked in a staircase. Accordingly, the first lower chip pad P1a of the first lower memory chip 141a, the first middle lower chip pad P1b of the first middle lower memory chip 141b, the first middle upper chip pad Plc of the first middle upper memory chip 141c, and the first upper chip pad P1d of the first upper memory chip 141d may be exposed in a staircase.

The second memory stack 142 may include a second lower memory chip 142a, second middle memory chips 142b and 142c, and a second upper memory chip 142d. The second middle memory chips 142b and 142c may include a second middle lower memory chip 142b and a second middle upper memory chip 142c. The second lower memory chip 142a, the second middle lower memory chip 142b, the second middle upper memory chip 142c, and the second upper memory chip 142d may include second chip pads P2a to P2d, respectively. For example, the second lower memory chip 142a may include the second lower chip pad P2a which is disposed adjacent to an edge on an upper surface, and the second middle lower memory chip 142b may include the second middle lower chip pad P2b which is disposed adjacent to an edge on an upper surface. The second middle upper memory chip 142c may include the second middle upper chip pad P2c which is disposed adjacent to an edge on an upper surface, and the second upper memory chip 142d may include the second upper chip pad P2d which is disposed adjacent to an edge on an upper surface. The second lower memory chip 142a, the second middle lower memory chip 142b, the second middle upper memory chip 142c, and the second upper memory chip 142d may be offset-stacked in a staircase. Accordingly, the second lower chip pad P2a of the second lower memory chip 142a, the second middle lower chip pad P2b of the second middle lower memory chip 142b, the second middle upper chip pad P2c of the second middle upper memory chip 142c, and the second upper chip pad P2d of the second upper memory chip 142d may be exposed in a staircase. According to another embodiment of the disclosure, the memory chips 141a to 141d and 142a to 142d may also be provided in a chiplet form.

The bonding wire structure 150 may include first and second chip bonding wires 151a to 151c and 152a to 152c, and first and second stack bonding wires 155 and 156. The first chip bonding wires 151a to 151c may electrically and physically connect the first chip pads P1a to P1d of the first memory chips 141a to 141d of the first memory stack 141 to each other. For example, the first chip bonding wires 151a to 151c may include a first lower chip bonding wire 151a connecting the first lower chip pad P1a to the first middle lower chip pad P1b, a first middle chip bonding wire 151b connecting the first middle lower chip pad P1b to the first middle upper chip pad P1c, and a first upper chip bonding wire 151c connecting the first middle upper chip pad Plc to the second upper chip pad P1d. The second chip bonding wires 152a to 152c may electrically and physically connect the second chip pads P2a to P2d of the second memory chips 142a to 142d of the second memory stack 142 to each other. For example, the second chip bonding wires 152a to 152c may include the second lower chip bonding wire 152a connecting the second lower chip pad P2a to the second middle lower chip pad P2b, a second middle chip bonding wire 152b connecting the second middle lower chip pad P2b to the second middle upper chip pad P2c, and the second upper chip bonding wire 152c connecting the second middle upper chip pad P2c to the second upper chip pad P2d. In other words, each of the first and second chip bonding wires 151a to 161c and 152a to 152c may connect two neighboring pads among the chip pads P1a to P1d or P2a to P2d of the stacked memory chips 141a to 141d or 142a to 142d. The first upper chip pad P1d of the first upper memory chip 141d of the first memory stack 141 may not be directly connected to the second lower chip pad P2a of the second lower memory chip 142a of the second memory stack 142.

The first stack bonding wire 155 may electrically and physically connect one of the first middle chip pads P1b and Plc of the first middle memory chips 141b and 141c of the first memory stack 141 to the first bond finger 126b. The second stack bonding wire 156 may electrically and physically connect one of the second middle chip pads P2b and P2c of the second middle memory chips 142b and 142c of the second memory stack 142 to the second bond finger 127b. The stack bonding wires 155 and 156 may be connected to one among the middle memory chips 141b, 141c, 142b, and 142c to reduce deviations of the electrical distances between the bond fingers 126b and 127b and the memory chips 141a to 141d and 142a to 142d. In the drawing, the first stack bonding wire 155 is illustrated to connect the first middle upper chip pad Plc of the first middle upper memory chip 141c to the first bond finger 126b. According to another embodiment of the disclosure, the first stack bonding wire 155 may connect the first middle lower chip pad P1b of the first middle lower memory chip 141b to the first bond finger 126b. In the drawing, the second stack bonding wire 156 is illustrated to connect the second middle upper chip pad P2b of the second middle lower memory chip 142b to the second bond finger 127b. According to another embodiment of the disclosure, the second stack bonding wire 156 may connect the second middle upper chip pad P2c of the second middle upper memory chip 142c to the second bond finger 127b. Because the first stack bonding wire 155 is connected to the first memory stack 141 stacked in the lower portion, it may be shorter than the second stack bonding wire 156 that is connected to the second memory stack 142 stacked in the upper portion. Accordingly, a signal difference may occur due to the difference between the length of the first stack bonding wire 155 and the length of the second stack bonding wire 156. According to the embodiment of the disclosure, the bonding wire structure 150 may be disposed to be adjacent to one side of the memory stack 140.

The first channel pad 131 of the control chip 130, the first channel connector 133, the first bonding pad 126a, the upper substrate interconnection 121, the first substrate via 125A, the lower substrate interconnection 123, the second substrate via 125B, the first bond finger 126b, the first stack bonding wire 155, and the first chip bonding wires 151 may form a first channel path. The second channel pad 132 of the control chip 130, the second channel connector 134, the second bonding pad 127a, the upper substrate interconnection 121, the second bond finger 127b, the second stack bonding wire 156, and the second chip bonding wires 152 may form a second channel path. The second stack bonding wire 156 of the second channel path may be longer than the first stack bonding wire 155 of the first channel path. Accordingly, the vertical distance between the upper substrate interconnection 121 and the lower substrate interconnection 123, that is, the second vertical length DV2 of the substrate vias 125A and 125B, is the first and second stack bonding wires 155 and 156 may compensate for the difference of the lengths of the electrical paths. The first substrate via 125A and the second substrate via 125B may be spaced apart from each other by the third horizontal distance D3. The second bonding pad 127a and the second bond finger 127b may be spaced apart from each other by the fourth horizontal distance D4. In other words, the difference between the third horizontal distance D3 and the fourth horizontal distance D4 may compensate for the difference in the lengths of the electrical paths between the first stack bonding wire 155 and the second stack bonding wire 156. Therefore, the difference in the signal paths caused by the difference in lengths of the bonding wires 155 and 156 that occurs according to the stacked position (i.e., height or level) of the memory chips 141a to 141d and 142a to 142d of the memory stacks 141 and 142 may be compensated for by the positions of the first and second bonding pads 126a and 127a, the positions of the first and second bond fingers 126b and 127b, the vertical lengths of the first and second substrate vias 125A and 125B, and the effective signal path of the upper and lower substrate interconnections 121 and 123.

The external bumps 115 may include a solder material or a metal. According to another embodiment of the disclosure, the semiconductor package 110 may further include an encapsulation material that covers the control chip 130 and the memory stack 140 over the substrate 120. The encapsulation material may include a resin, e.g., epoxy molding compound (EMC).

FIGS. 10A and 10B are top views illustrating a wire bonding method in accordance with the embodiments of the present disclosure. Referring to FIGS. 10A and 10B, the chip pads P1a to P1d and P2a to P2d may be disposed to be aligned or overlap on the same straight line in the same direction, for example, a column direction. Accordingly, the chip bonding wires 151 and 152 may be disposed to form a straight line extending in the column direction. The first and second bond fingers 126b and 127b may be disposed not to be aligned with or overlap with the chip pads P1a to P1d and P2a to P2d in the column direction. For example, the first and second bond fingers 126b and 127b may be disposed to be offset from the chip pads P1a to P1d and P2a to P2d in the row direction. Alternatively, the first and second bond fingers 126b and 127b may be disposed to be diagonally spaced apart from the chip pads P1a to P1d and P2a to P2d. Accordingly, the first and second stack bonding wires 155 and 156 may be disposed to extend in straight and diagonal directions formed by the chip bonding wires 151 and 152, respectively.

Referring to FIG. 10A, the first bond finger 126b and the second bond finger 127b may be aligned or overlap in the row direction. For example, the first bond finger 126b and the second bond finger 127b may be disposed on the same straight line in the row direction. The first bond finger 126b and the second bond finger 127b may be disposed in the opposite directions in the row direction based on the chip pads P1a to P1d and P2a to P2d. Accordingly, the first stack bonding wire 155 and the second stack bonding wire 156 may be disposed in different directions, for example, in a direction that is diagonal to the confronting direction.

Referring to FIG. 10B, the first bond finger 126b and the second bond finger 127b may not be aligned or overlap in the row direction. For example, the first bond finger 126b and the second bond finger 127b may be disposed on different straight lines in the row direction. The first bond finger 126b and the second bond finger 127b may be disposed in the same direction in the row direction based on the chip pads P1a to P1d and P2a to P2d. Accordingly, the first stack bonding wire 155 and the second stack bonding wire 156 may be disposed in the same direction, for example, in a direction that is diagonal to the same direction.

According to an embodiment of the disclosure, because differences in the electrical signal paths between the memory stacks are compensated for, semiconductor devices and semiconductor packages may have small temporal signal differences. Accordingly, semiconductor devices and semiconductor packages that are advantageous for high-speed operation may be used.

While the present disclosure has been described with respect to specific embodiments, it will be apparent to those skilled in the art that various changes and modifications may be made without departing from the spirit and scope of the invention as defined in the following claims.

What is claimed is:

1. A semiconductor package, comprising:
a control chip and a memory stack mounted on a substrate, wherein the memory stack includes a first memory stack and a second memory stack stacked over the first memory stack; and
first and second stack bonding wires,
wherein the control chip includes a first channel pad and a second channel pad,
wherein the substrate includes:
a first electrical path including:
a first bonding pad electrically connected to the first channel pad,
a first substrate interconnection electrically connected to the first bonding pad, and
a first bond finger electrically connected to the first substrate interconnection; and
a second electrical path including:
a second bonding pad electrically connected to the second channel pad,
a second substrate interconnection electrically connected to the second bonding pad, and
a second bond finger electrically connected to the second substrate interconnection, and
wherein:
the first stack bonding wire electrically connects the first bond finger to the first memory stack,
the second stack bonding wire electrically connects the second bond finger to the second memory stack,
the first stack bonding wire is shorter than the second stack bonding wire, and
the first electrical path is longer than the second electrical path.

2. The semiconductor package of claim 1,
wherein:
the substrate includes a chip mounting area where the control chip is mounted and a stack mounting area where the first and second memory stacks are mounted, and
the first bonding pad and the second bonding pad are disposed in the chip mounting area, and
the first bonding pad is farther from the stack mounting area than the second bonding pad.

3. The semiconductor package of claim 1,
wherein the substrate further includes:
a first substrate via disposed in the chip mounting area to electrically connect the first bonding pad to the first substrate interconnection; and
a second substrate via disposed in the stack mounting area to electrically connect the first substrate interconnection to the first bond finger.

4. The semiconductor package of claim 3,
wherein a first electrical connection distance of the first substrate interconnection from a portion connected to the first substrate via to a portion connected to the second substrate via is longer than a second electrical connection length of the second substrate interconnection from a portion connected to the second bonding pad to a portion connected to the second bond finger.

5. The semiconductor package of claim 3, further comprising:
a third substrate via electrically connecting the second bonding pad and the second substrate interconnection; and
a fourth substrate via electrically connecting the second substrate interconnection to the second bond finger,
wherein vertical lengths of the first and second substrate vias are greater than vertical lengths of the third and fourth substrate vias.

6. The semiconductor package of claim 5, wherein a first electrical connection distance of the first substrate interconnection from a portion connected to the first substrate via to a portion connected to the second substrate via is longer than a second electrical connection length of the second substrate interconnection from a portion connected to the third substrate via to a portion connected to the fourth substrate via.

7. The semiconductor package of claim 1, further comprising:
a first chip connector electrically connecting the first channel pad to the first bonding pad; and
a second chip connector electrically connecting the second channel pad to the second bonding pad,
wherein an electrical path from the first chip connector to the first bond finger is longer than an electrical path from the second chip connector to the second bond finger.

8. The semiconductor package of claim 1, further comprising:
a first channel wire electrically connecting the first channel pad to the first bonding pad; and
a second channel wire electrically connecting the second channel pad to the second bonding pad,
wherein an electrical path from the first channel pad to the first bond finger is longer than an electrical path from the second channel pad to the second bond finger.

9. The semiconductor package of claim 1,
wherein the first memory stack includes a first lower memory chip, a first middle lower memory chip, a first middle upper memory chip, and a first upper memory chip that are stacked in a staircase,
wherein:
the first lower memory chip includes a first lower chip pad,
the first middle lower memory chip includes a first middle lower chip pad,
the first middle upper memory chip includes a first middle upper chip pad,
the first upper memory chip includes a first upper chip pad, and
the first stack bonding wire connects one of the first middle lower chip pad and the first middle upper chip pad to the first bond finger,
wherein the second memory stack includes a second lower memory chip, a second middle lower memory chip, a second middle upper memory chip, and a second upper memory chip that are stacked in a staircase,
wherein:
the second lower memory chip includes a second lower chip pad,
the second middle lower memory chip includes a second middle lower chip pad,
the second middle upper memory chip includes a second middle upper chip pad,
the second upper memory chip includes a second upper chip pad, and
the second stack bonding wire connects one of the second middle lower chip pad and the second middle upper chip pad to the second bond finger.

10. The semiconductor package of claim 9,
wherein: in a top view,
the first lower chip pad, the first middle lower chip pad, the first middle upper chip pad, the first upper chip pad, the second lower chip pad, the second middle lower chip pad, the second middle upper chip pad, and the second upper chip pad are disposed to be aligned on a first straight line, and
wherein the first bond finger and the second bond finger are disposed not to be aligned with the first straight line.

11. The semiconductor package of claim 10,
wherein:
the first bond finger is disposed to be spaced apart from the first straight line in a first direction,
the second bond finger is disposed to be spaced apart from the first straight line in a second direction, and
the first direction and the second direction are opposite directions to each other.

12. The semiconductor package of claim 9, further comprising:
a first lower chip bonding wire connecting the first lower chip pad to the first middle lower chip pad,
a first middle chip bonding wire connecting the first middle lower chip pad to the first middle upper chip pad,
a first upper chip bonding wire connecting the first middle upper chip pad to the second upper chip pad,
a second lower chip bonding wire connecting the second lower chip pad to the second middle lower chip pad,
a second middle chip bonding wire connecting the second middle lower chip pad to the second middle upper chip pad, and
a second upper chip bonding wire connecting the second middle upper chip pad to the second upper chip pad,
wherein the first upper chip pad and the second lower chip pad are not directly connected to each other.

13. The semiconductor package of claim 12,
wherein:
the first lower chip bonding wire, the first middle chip bonding wire, the first upper chip bonding wire, the second lower chip bonding wire, the second middle chip bonding wire, and the second upper chip bonding wire are disposed to form a straight line, and
the first stack bonding wire and the second stack bonding wire are disposed to be diagonal to the straight line.

14. The semiconductor package of claim 13,
wherein:
the first stack bonding wire is disposed to extend from the straight line in a first diagonal direction, and
the second stack bonding wire is disposed to extend from the straight line in a second diagonal direction, and
the first diagonal direction is different from the second diagonal direction.

15. A semiconductor package, comprising:
a substrate having an upper surface and a lower surface;
a control chip and a memory stack mounted on the upper surface of the substrate, wherein the memory stack includes a first memory stack and a second memory stack stacked over the first memory stack in a direction toward the control chip;
a first channel connector electrically connecting a first bonding pad of the substrate to a first channel pad of the control chip;
a second channel connector electrically connecting a second bonding pad of the substrate to a second channel pad of the control chip;
a first stack bonding wire disposed on a first side of the memory stack and electrically connecting a first bond finger of the substrate to the first memory stack; and
a second stack bonding wire disposed on the first side of the memory stack and electrically connecting a second bond finger of the substrate to the second memory stack,
wherein the substrate includes:
a first middle substrate interconnection;
a second middle substrate interconnection;
a first substrate via that vertically passes through the first middle substrate interconnection and electrically connects the first bonding pad to the second middle substrate interconnection; and
a second substrate via that vertically passes through the first middle substrate interconnection and electrically connects the first bond finger to the second middle substrate interconnection, and
wherein the first stack bonding wire is shorter than the second stack bonding wire, and
wherein a first electrical path from the first bonding pad to the first bond finger is longer than a second electrical distance from the second bonding pad to the second bond finger.

16. The semiconductor package of claim 15,
wherein:
the substrate further includes an upper substrate interconnection that is disposed adjacent to the upper surface, and
the upper substrate interconnection electrically connects the first bond finger to the second bond finger.

17. The semiconductor package of claim 16,
wherein the upper substrate interconnection includes:
a first portion extending horizontally from the first bonding pad;
a second portion extending horizontally from the second bonding pad;
a third portion extending horizontally from the first bond finger; and
a fourth portion extending horizontally from the second bond finger,
wherein:
the first portion is connected to the first substrate via, and
the third portion is connected to the second substrate via.

18. The semiconductor package of claim 15,
wherein the substrate further includes a lower substrate interconnection that is disposed adjacent to the lower surface, and
wherein the lower substrate interconnection provides pad structures for contacting external bumps for connection to an external system.

19. The semiconductor package of claim 15,
wherein the first memory stack includes a first lower memory chip, a first middle lower memory chip, a first middle upper memory chip, and a first upper memory chip that are stacked in a staircase, and
wherein:
the first lower memory chip includes a first lower chip pad,
the first middle lower memory chip includes a first middle lower chip pad,
the first middle upper memory chip includes a first middle upper chip pad,
the first upper memory chip includes a first upper chip pad,
the first stack bonding wire connects one among the first middle lower chip pad and the first middle upper chip pad to the first bond finger,
the second memory stack includes a second lower memory chip, a second middle lower memory chip, a second middle upper memory chip, and a second upper memory chip that are stacked in a staircase, and
the second lower memory chip includes a second lower chip pad,
the second middle lower memory chip includes a second middle lower chip pad,
the second middle upper memory chip includes a second middle upper chip pad,
the second upper memory chip includes a second upper chip pad, and
the second stack bonding wire connects one among the second middle lower chip pad and the second middle upper chip pad to the second bond finger.

20. The semiconductor package of claim 15,
wherein:
the first bonding pad is disposed farther from the first bond finger and the second bond finger than the second bonding pad, and
the second bond finger is disposed farther from the first bonding pad and the second bonding pad than the first bond finger.
